(19) United States
(12) Patent Application Publication
(10) Pub. No.: US 2024/0321479 A1
(43) Pub. Date: Sep. 26, 2024

(54) COMPOSITE PASTE FOR POWER DEVICES PACKAGING AND PREPARATION METHOD THEREFOR

(71) Applicant: Harbin University of Science and Technology, Harbin (CN)

(72) Inventors: Yang Liu, Harbin (CN); Ke Li, Harbin (CN); Zehou Li, Harbin (CN); Jianbo Xin, Harbin (CN)

(21) Appl. No.: 18/735,040

(22) Filed: Jun. 5, 2024

Related U.S. Application Data
(63) Continuation of application No. PCT/CN2022/134588, filed on Nov. 28, 2022.

(30) Foreign Application Priority Data
Dec. 6, 2021 (CN) 202111481040.9

(51) Int. Cl. H01B 1/22; C09D 11/033; C09D 11/037; C09D 11/102; C09D 11/52; C09K 5/14; H05K 7/20

(52) U.S. Cl. CPC H01B 1/22; C09D 11/033; C09D 11/037; C09D 11/102; C09D 11/52; C09K 5/14; H05K 7/209

(57) ABSTRACT

Disclosed are a composite paste for power devices packaging and a preparation method therefor, falling within the field of packaging materials for power devices. The composite paste for power devices packaging of the present disclosure is prepared from a silver-copper filler and an organic carrier, and the silver-copper filler is a mixture of flaky silver and spherical copper. The method of the present disclosure includes: step 1: stirring a silver-copper filler and an organic carrier until uniform mixing to obtain a mixed paste; and step 2: performing three-stage dispersion grinding on the mixed paste to obtain the composite paste for power devices packaging. The preparation process of the present disclosure is simple, and the obtained composite paste has low cost, good thermal conductivity, no obvious electromigration failure and excellent mechanical properties, significantly improving the reliability of power device packaging.

### CROSS-REFERENCE TO RELATED APPLICATIONS

This application is a continuation of PCT/CN2022/134588, filed Nov. 28, 2022 and claims priority of Chinese Patent Application No. 202111481040.9, filed on Dec. 6, 2021, the entire contents of which are incorporated herein by reference.

### TECHNICAL FIELD

The present disclosure belongs to the field of packaging materials for power devices, and particularly relates to a composite paste for power devices packaging and a preparation method therefor.

### BACKGROUND

The utilization of third-generation semiconductor silicon carbide (SiC) and its power devices, notably in applications such as electric vehicles, photovoltaic, 5th-generation (5G) big data, wind power generation and other application scenarios, has become widespread. Due to the wide band-gap range and high switching frequency, the selection of packaging materials for these devices becomes critical. Traditional Sn-based solder cannot meet the service requirements of high-power chip devices. At present, a high-temperature tin-based solder Au—Sn and a silver sintered solder paste to be developed can meet the service requirements of power chips, but the large-scale application is limited to some extent due to the high cost. The electromigration property of silver has great influence on the properties of the silver sintered layer, including shear strength and thermal conductivity. Additionally, the silver sintered layer is more prone to failure during service, posing challenges to device reliability. The relatively high cost of sintered silver presents a substantial obstacle to its widespread adoption. Therefore, there is an urgent necessity to develop microelectronic packaging materials capable of withstanding extreme environments such as high temperature.

For power devices like SiC, the electrical and thermal conductivity of packaging materials must meet specific requirements. It is particularly important to develop a low-cost composite solder paste with reduced silver content to reduce electromigration failure and apply the composite solder paste to a packaging and connecting material of power devices.

### SUMMARY

An object of the present disclosure is to provide a composite paste for power devices packaging and a preparation method therefor, addressing the technical problems of high cost and poor electromigration resistance property of existing silver sintered pastes.

The composite paste for power devices packaging of the present disclosure is prepared from a silver-copper filler and an organic carrier, and the silver-copper filler is a mixture of flaky silver and spherical copper.

In a further limitation, a mass ratio of the silver-copper filler to the organic carrier is 8:(1.5-2.5).

In a further limitation, a mass ratio of silver to copper in the silver-copper filler is 6:(3.5-4.5).

In a further limitation, the flaky silver has a diameter of 1 μm-3 μm, and the spherical copper has a diameter of 1 μm-3 μm.

In a further limitation, the organic carrier is prepared from 20%-40% of terpilenol, 40%-60% of 2-ethyl-1,3-hexanediol, and 10%-30% of polyethylene glycol (PEG) by mass fraction.

In a further limitation, a specific preparation process of the organic carrier includes: uniformly mixing terpilenol, 2-ethyl-1,3-hexanediol and PEG through magnetic stirring under a constant temperature water bath condition of 60-80° C., with continuing constant temperature stirring for 0.5 h-1.5 h to obtain the organic carrier.

In a further limitation, the magnetic stirring is conducted at a speed of 100 rpm-200 rpm.

A preparation method for a composite paste for power devices packaging of the present disclosure includes the steps of:
step 1: stirring a silver-copper filler and an organic carrier until uniform mixing to obtain a mixed paste; and
step 2: performing three-stage dispersion grinding on the mixed paste, including grinding at a gap of 60 μm-90 μm for 5 min-8 min, then grinding at a gap of 30 μm-60 μm for 5 min-8 min, and grinding at a gap of 5 μm-10 μm for 3 min-5 min, to obtain a composite paste for power devices packaging.

In a further limitation, a dispersity of the composite paste for power devices packaging obtained by performing three-stage dispersion grinding on the mixed paste in step 2 is 5 μm based on a scraper fineness gauge.

Compared with the prior art, the present disclosure has the following remarkable effects.

In the present disclosure, the electromigration resistance property of the composite paste is improved and the cost is reduced by designing the shape composite of silver and copper. The obtained composite paste has low cost, good thermal conductivity, and no obvious electromigration failure, significantly improving the reliability of power device packaging. In the present disclosure, a packaging material for power device interconnection with a simple preparation process, excellent mechanical properties and low cost is obtained, having the specific following advantages.
(1) In the present disclosure, the strength of sintered interconnection joint is enhanced by the shape design of silver and copper; and at the same time, the optimal shape composite paste is formed by precisely controlling the silver content in the composite paste. The reliability of the sintered joint of the composite paste is tested at a temperature of −40° C.-120° C. for retention times of 15 min at high-temperature and low-temperature stages. The shear strength of the joint of the composite paste after 1100 cycles is obtained, as shown in FIG. 4.
(2) In the present disclosure, taking the micron-sized silver-copper filler as a raw material for paste preparation, the silver-copper composite sintered paste prepared by the simple and repeated process can be applied to the pressure-assisted sintering process, meeting the requirements of sintering processes, and is applied to the packaging of power devices.
(3) In the present disclosure, the low residue of the prepared organic carrier in the sintering process can improve the overall performance of sintered tissue joint.

### BRIEF DESCRIPTION OF THE DRAWINGS

FIG. 1 is a comparison diagram showing minimum shear strengths of interconnection joints of composite pastes in Example 1 and Comparative Examples 1-3;

FIG. 2 is a comparison diagram showing electromigration resistance properties of the interconnection joints of the composite pastes in Example 1 and Comparative Examples 1-3;

FIG. 3 is a comparison diagram showing thermal conductivity properties of the composite pastes in Example 1 and Comparative Examples 1-3; and

FIG. 4 is a comparison diagram showing shear properties of the interconnection joints of the composite pastes in Example 1 and Comparative Examples 1-3 after temperature cycling.

### DETAILED DESCRIPTION

Example 1: a composite paste for power devices packaging in the example is prepared from a silver-copper filler and an organic carrier. The silver-copper filler is a mixture of flaky silver and spherical copper. A mass ratio of the silver-copper filler to the organic carrier is 8:2, and a mass ratio of the flaky silver to the spherical copper in the silver-copper filler is 6:4. The flaky silver has a diameter of 2 μm, and the spherical copper has a diameter of 2 μm. The organic carrier is prepared from 30% of terpilenol, 50% of 2-ethyl-1,3-hexanediol and 20% of PEG 2000 by mass fraction. A specific preparation process of the organic carrier includes that: terpilenol, 2-ethyl-1,3-hexanediol and PEG 2000 were uniformly mixed by means of magnetic stirring under a constant temperature water bath condition of 70° C., a rotating speed of the magnetic stirring being 150 rpm, and constant temperature stirring is continued for 1 h to obtain the organic carrier.

A preparation method for a composite paste for power devices packaging described in Example 1 includes the following steps.
In step 1: a silver-copper filler and an organic carrier were stirred until uniform mixing to obtain a mixed paste.
In step 2: three-stage dispersion grinding was performed on the mixed paste, including grinding at a gap of 75 μm for 6 min, then grinding at a gap of 45 μm for 6 min, and grinding at a gap of 8 μm for 4 min, to obtain a composite paste for power devices packaging with a dispersity of 5 μm based on a scraper fineness gauge.

Comparative Example 1: the example differed from Example 1 in that: a silver-copper filler was a mixture of spherical silver and flaky copper. Other steps and parameters were the same as in Example 1.

Comparative Example 2: the example differed from Example 1 in that: a silver-copper filler was a mixture of flaky silver and flaky copper. Other steps and parameters were the same as in Example 1.

Comparative Example 3: the example differed from Example 1 in that: a silver-copper filler was a mixture of spherical silver and spherical copper. Other steps and parameters were the same as in Example 1.

### Detection Tests

Test I: the minimum shear strengths of interconnection joints manufactured by composite pastes obtained in Example 1 and Comparative Examples 1-3 were detected. The specific procedures were as follows.

The manufacturing process of interconnection joints: in (1), the composite pastes obtained in Example 1 and Comparative Examples 1-3 were printed on surfaces of copper substrates by means of steel mesh printing, a steel mesh having a thickness of 100 μm and openings of 2 mm×2 mm, and after printing, organic substances in the composite pastes were removed by baking for 15 min in an oven at 120° C. under the protection of nitrogen.

In (2), chips were mounted on positions of the baked composite pastes and sintered for 300 s at 250° C. and 20 MPa to complete the interconnection of the chips and the substrates, to obtain the interconnection joints.

Thrust test parameters include a height of a blade of 30 microns and a speed of 100 μm/min.

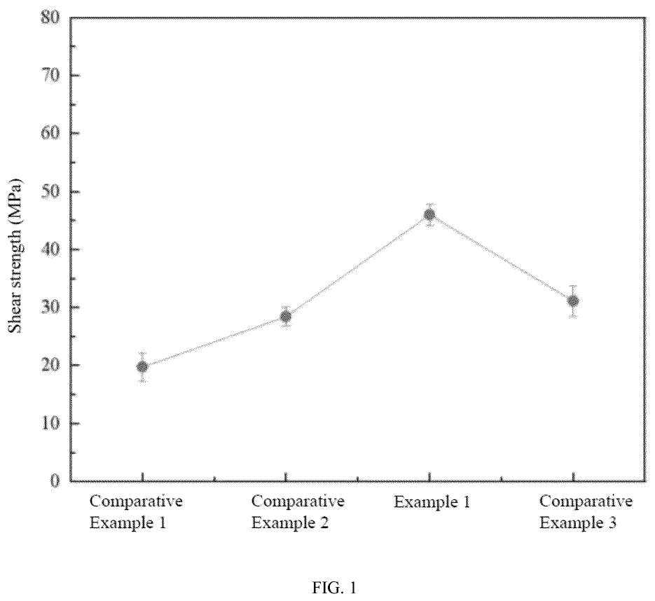

The test results are shown in FIG. 1. It can be seen from FIG. 1 that the minimum shear strength in Example 1 is 46.01 MPa, whereas that in Comparative Examples 1-3 are 19.74 MPa, 28.45 MPa and 31.13 MPa, respectively. The minimum shear strength of the interconnection joint obtained using the composite paste in Example 1 of the present disclosure is significantly higher than those in Comparative Examples 1-3, with excellent properties.

Test II: electromigration resistance properties of interconnection joints manufactured by composite pastes obtained in Example 1 and Comparative Examples 1-3 were detected. The specific procedures were as follows.

The manufacturing process of interconnection joints: in (1), the composite pastes obtained in Example 1 and Comparative Examples 1-3 were printed on surfaces of copper substrates by means of steel mesh printing, a steel mesh having a thickness of 100 μm and openings of 2 mm×2 mm; and after printing, organic substances in the composite pastes were removed by baking for 15 min in an oven at 120° C. under the protection of nitrogen.

In (2), chips were mounted on positions of the baked composite pastes and sintered for 300 s at 250° C. and 20 MPa to complete the interconnection of the chips and the substrates, to obtain the interconnection joints.

The test process was as follows. A copper plate having a thickness of 1 mm and a width of 2 mm was taken as a specimen for the electromigration test, and an area of a connection region was 4 mm². The interconnection joints connected by the composite pastes obtained in Example 1 and Comparative Examples 1-3 were detected at a temperature of 200° C. and a current density of 5×10₄ A/cm².

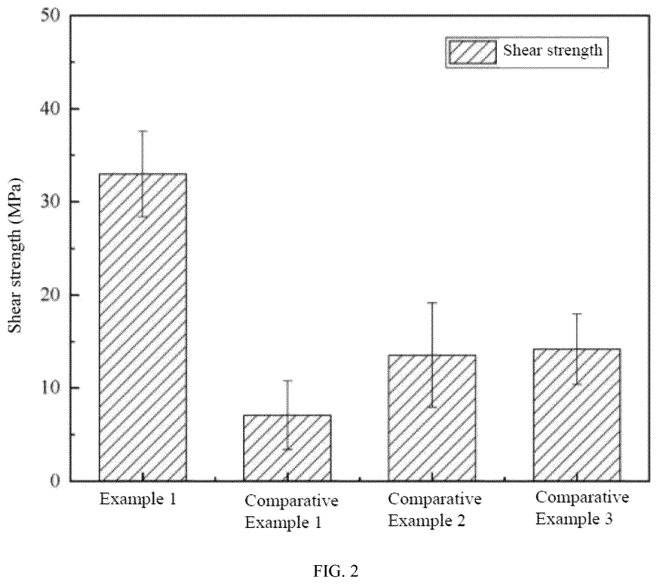

The results are shown in FIG. 2. It can be seen from FIG. 2 that the minimum shear strength of the interconnection joint of the composite paste in Example 1 is 32.98 MPa after 480 h, which decreases only by 27%, while the minimum shear strengths of the interconnection joints of the composite pastes in Comparative Examples 1-3 are 7.1 MPa, 13.55 MPa, and 14.19 MPa, which decrease by 64%, 52.4%, and 54.4%, respectively.

Test III: thermal conductivity properties of interconnection joints manufactured by composite pastes obtained in Example 1 and Comparative Examples 1-3 were detected. The specific procedures were as follows.

Preparation of thermal conductive specimens: the composite pastes in Example 1 and Comparative Examples 1-3 were printed on surfaces of ceramic substrates using a printing mold with a thickness of 1.5 mm and a diameter of 13 mm; and after printing, organic substances in the composite pastes were removed by baking for 15 min in an oven at 120° C. under the protection of nitrogen and sintered for 300 s at 250° C. and 20 MPa to obtain the thermal conductive specimens.

Test processes: the test processes were carried out in the nitrogen environment at a sampling rate of 300 pps. During the tests, specific heats of the specimens of Example 1 and Comparative Examples 1-3 were measured simultaneously.

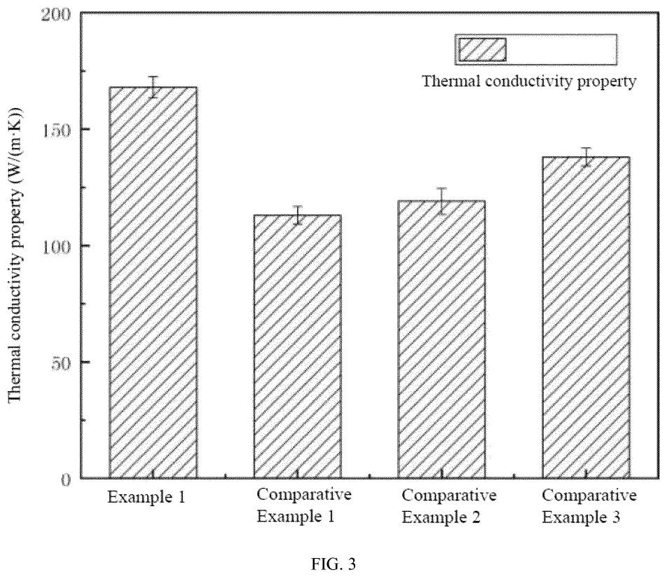

The results are shown in FIG. 3. It can be seen from FIG. 3 that thermal conductivities of Example 1 and Comparative Examples 1-3 are 168 W/(m·K), 113 W/(m·K), 119 W/(m·K), and 138 W/(m. K), respectively.

Test IV: the reliabilities of interconnection joints manufactured by composite pastes obtained in Example 1 and Comparative Examples 1-3 under temperature cycling were detected. The specific procedures were as follows.

The manufacturing process of interconnection joints: in (1), the composite pastes obtained in Example 1 and Comparative Examples 1-3 were printed on surfaces of copper substrates by means of steel mesh printing, a steel mesh having a thickness of 100 μm and openings of 2 mm×2 mm; and after printing, organic substances in the composite pastes were removed by baking for 15 min in an oven at 120° C. under the protection of nitrogen.

In (2), chips were mounted on positions of the baked composite pastes and sintered for 300 s at 250° C. and 20 MPa to complete the interconnection of the chips and the substrates, to obtain the interconnection joints.

Temperature cycling treatments: a temperature interval of −40-125° C. was set in temperature cycling, at heating and cooling rates of 5 K/min for retention times of 15 min at high-temperature and low-temperature stages, according to JEDEC standards. Specimens of Example 1 and Comparative Examples 1-3 were taken for interconnection strength tests at 100, 300, 500, 700, 900, and 1100 cycles.

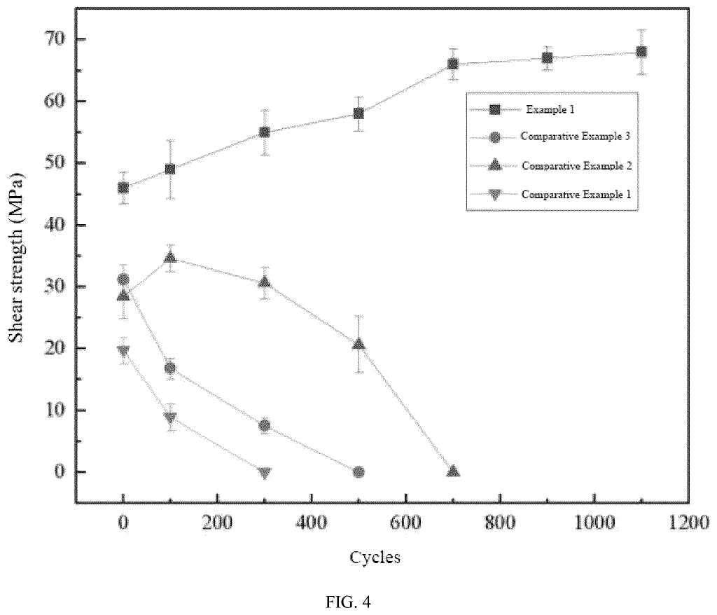

Stability tests after temperature cycling: the interconnection strength tests were performed on a thruster machine with a shear height of 30 microns and a shear rate of 100 μm/min. The results of shear tests are shown in FIG. 4. Example 1 has the higher reliability with a 46% increase in shear strength of the joint to 68 MPa after 1100 cycles, Comparative Example 1 fails completely after 300 cycles, Comparative Example 2 fails completely after 700 cycles, and Comparative Example 3 fails completely after 500 cycles, with Example 1 showing the higher reliability.

1. A composite paste for power devices packaging, prepared from a silver-copper filler and an organic carrier, the silver-copper filler being a mixture of flaky silver and spherical copper,
a mass ratio of the silver-copper filler to the organic carrier being 8:(1.5-2.5),
a mass ratio of silver to copper in the silver-copper filler being 6:(3.5-4.5), and
the flaky silver having a diameter of 1 μm-3 μm, and the spherical copper having a diameter of 1 μm-3 μm.

2. The composite paste for power devices packaging according to claim 1, wherein the organic carrier is prepared from 20%-40% of terpilenol, 40%-60% of 2-ethyl-1,3-hexanediol, and 10%-30% of polyethylene glycol (PEG) by mass fraction.

3. The composite paste for power devices packaging according to claim 2, wherein a specific preparation process of the organic carrier comprises: uniformly mixing terpilenol, 2-ethyl-1,3-hexanediol and PEG by means of magnetic stirring under a constant temperature water bath condition of 60-80° C., with continuing constant temperature stirring for 0.5 h-1.5 h to obtain the organic carrier.

4. The composite paste for power devices packaging according to claim 3, the magnetic stirring is conducted at a speed of 100 rpm-200 rpm.

5. A preparation method for a composite paste for power devices packaging according to claim 1, comprising the steps of:
step 1: stirring a silver-copper filler and an organic carrier until uniform mixing to obtain a mixed paste; and
step 2: performing three-stage dispersion grinding on the mixed paste, comprising grinding at a gap of 60 μm-90 μm for 5 min-8 min, then grinding at a gap of 30 μm-60 μm for 5 min-8 min, and grinding at a gap of 5 μm-10 μm for 3 min-5 min, to obtain a composite paste for power devices packaging.

6. A preparation method for a composite paste for power devices packaging according to claim 2, comprising the steps of:
step 1: stirring a silver-copper filler and an organic carrier until uniform mixing to obtain a mixed paste; and
step 2: performing three-stage dispersion grinding on the mixed paste, comprising grinding at a gap of 60 μm-90 μm for 5 min-8 min, then grinding at a gap of 30 μm-60 μm for 5 min-8 min, and grinding at a gap of 5 μm-10 μm for 3 min-5 min, to obtain a composite paste for power devices packaging.

7. A preparation method for a composite paste for power devices packaging according to claim 3, comprising the steps of:
step 1: stirring a silver-copper filler and an organic carrier until uniform mixing to obtain a mixed paste; and
step 2: performing three-stage dispersion grinding on the mixed paste, comprising grinding at a gap of 60 μm-90 μm for 5 min-8 min, then grinding at a gap of 30 μm-60 μm for 5 min-8 min, and grinding at a gap of 5 μm-10 μm for 3 min-5 min, to obtain a composite paste for power devices packaging.

8. A preparation method for a composite paste for power devices packaging according to claim 4, comprising the steps of:
step 1: stirring a silver-copper filler and an organic carrier until uniform mixing to obtain a mixed paste; and
step 2: performing three-stage dispersion grinding on the mixed paste, comprising grinding at a gap of 60 μm-90 μm for 5 min-8 min, then grinding at a gap of 30 μm-60 μm for 5 min-8 min, and grinding at a gap of 5 μm-10 μm for 3 min-5 min, to obtain a composite paste for power devices packaging.

9. The preparation method for a composite paste for power devices packaging according to claim 5, wherein a dispersity of the composite paste for power devices packaging obtained by performing three-stage dispersion grinding on the mixed paste in step 2 is 5 μm based on a scraper fineness gauge.
